(19) United States
(12) Patent Application Publication
(10) Pub. No.: US 2026/0271685 A1
(43) Pub. Date: Sep. 10, 2026

(54) DEEP TRENCH ISOLATION STRUCTURES AND METHODS OF FORMING THE SAME

(71) Applicant: Taiwan Semiconductor Manufacturing Company, LTD., Hsinchu (TW)

(72) Inventor: Yen Chang Tseng, Hsinchu (TW)

(21) Appl. No.: 19/070,755

(22) Filed: Mar. 5, 2025

(51) Int. Cl. H01L 21/762; H10D 84/83

(52) U.S. Cl. CPC H10W 10/17; H10D 84/83; H10W 10/0143

(57) ABSTRACT

A Deep Trench Insulator (DTI) structure and method of forming the same including forming one or more deep trench isolation (DTI) structures on one or more STI structures, each of the DTI structures including a DTI trench depth extending from a DTI trench top to a DTI trench bottom, and the DTI trench formed to extend entirely through the STI trench bottom. Furthermore, according to another example DTI structure, the DTI structure includes one or more deep trench isolation (DTI) polygonal ring shaped structures, each of the DTI polygonal ring shaped structure having a DTI trench including a DTI trench depth extending from a DTI trench top to the DTI trench bottom.

### BACKGROUND

The following relates to semiconductor integrated circuits (ICs), IC fabrication processes, isolation structures for IC devices and (sub-)circuits, and the like.

For proper IC operation, constituent electronic components (e.g., single electronic devices, or sub-circuits of the IC) may be electrically isolated from one another to avoid deleterious interactions. The following discloses deep trench isolation (DTI) structures, and methods of forming the same, with certain advantages as disclosed herein.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross sectional view of an integrated circuit (IC) including a deep trench isolation (DTI) structure according to an example embodiment of this disclosure, the DTI structure having a structure (Embodiment 1A) including first and second DTI structures located on and extending through respective STI structures, where DTI trenches are formed to extend entirely through the STI trench bottom.

FIG. 1B is a top view of the IC including a DTI structure shown in FIG. 1A.

FIG. 1C is a cross sectional detail view of a DTI structure (Embodiment 1B) according to an example embodiment of this disclosure, the DTI structure including first and second DTI structures located on and extending through respective STI structures, where the DTI trench have tapered sidewalls and rounded trench bottoms.

FIG. 1D is a cross sectional detail view of a DTI structure (Embodiment 1C) according to an example embodiment of this disclosure, the DTI structure including first and second DTI structures located on and extending through respective STI structures, where each of the first and second DTI structures have two trenches spaced a distance from one another, and each of the two trenches has a channel stop layer within the DTI trench, the channel stop layer including the implantation of ions distributed along the DTI trench sidewalls and along the DTI trench bottom.

FIG. 1E shows an IC fabrication processing sequence to form a plurality of DTI trenches on STIs according to an example embodiment of this disclosure, the sequence including an active region/area processing stage, a STI formation processing stage and a DTI formation processing stage.

FIG. 2 is a top view of an IC die or structure including a DTI polygon ring shaped structure encircling an active region/area of the IC according to an example embodiment of this disclosure, the active region/area including a plurality of (BCD) or other devices, and the DTI polygon ring shaped structure not limited to being located at a STI (Embodiment 2A) or where the DTI polygon ring shaped structure is located at a STI (Embodiment 2B) where the DTI trench depth extends entirely through the STI trench bottom.

FIG. 3 a top view of an IC die or structure including a DTI polygon ring shaped structure encircling an active region/area of the IC according to an example embodiment of this disclosure, the active region/area including a plurality of Bipolar-CMOS-DMOS (BCD) or other devices, and the DTI polygon ring shaped structure including an inner polygon shaped DTI ring and an outer polygon shaped DTI ring, where each of the DTI polygon ring shaped structures is not limited to being located at a STI (Embodiment 3A) or where each of the DTI polygon ring shaped structures is located at a STI (Embodiment 3B) where the DTI trench depth extends entirely through the STI trench bottom.

FIGS. 4A and 4B are flow charts of methods of forming a deep trench isolation structure in a semiconductor substrate according to an example embodiment of this disclosure.

FIGS. 5A and 5B are flow charts of methods of forming a deep trench isolation structure in a semiconductor substrate according to an example embodiment of this disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer,” as used herein, may include a single layers or multiple layers.

The term “conductive feature,” as may be used herein refers to a metallization layer contact, patterned metallization layer contact, or other electrical metal contact.

The term “intermetal dielectric” (IMD) film or layer, as may be used herein, refers to a dielectric/insulation material(s) layer between two metal layers.

The term “interlayer dielectric” (ILD) layer, as may be used herein, refers to an insulating structure of material(s) placed between two conductive layers.

The term “line” and “metal line,” as may be used herein, is a conductive path that is created during the back end of line (BEOL) process and transmits electrical signals through a semiconductor chip's circuit pattern.

The term “orthogonal axis”, as used herein, refers to an axis substantially at 90 degrees relative to a longitudinal axis of a structure.

Some embodiments disclosed herein relate to semiconductor devices, including DTI structures located or formed on at least one shallow trench isolation (STI) structure formed on a semiconductor substrate, each of the DTI structures including a DTI trench having a DTI trench top, a DTI trench bottom, DTI trench sidewalls, a DTI trench depth extending from the DTI trench top to the DTI trench bottom, and the DTI trench formed to extend entirely through a STI trench bottom.

Additional embodiments disclosed herein, include DTI structures including one or more polygonal ring shaped structures, each of the DTI polygonal ring shaped structures having a DTI trench, and the DTI polygonal ring shaped structures encircling an active region/area of a semiconductor structure or device.

Modem day integrated chips comprise millions or billions of semiconductor devices formed on a semiconductor substrate (e.g., silicon). Integrated chips (ICs) may use many different types of semiconductor devices, depending on an application of an IC. To reduce the area of the IC, the semiconductor devices may be formed in close proximity to one another. To prevent interference amongst the semiconductor devices, techniques and/or features for device isolation are incorporated into semiconductor devices and structures. Among other things, DTI structures can provide electrical isolation amongst semiconductor devices to improve device performance without sacrificing a large area on the IC. In addition, DTI structures can provide excellent electromagnetic interference (EMI) isolation for some semiconductor devices.

Some existing DTI structures suffer from issues related to the breakdown voltage (BV) of the semiconductor device's degrading when operated at higher voltages, thereby producing device leakage current. Furthermore, some existing designs suffer from having different BVs depending on whether or not the device is fabricated using DTIs and shallow trench isolation (STI) structures, or only STI structures. Some existing techniques and structures to mitigate the degradation of BV is to increase the isolation spacing of the devices by a design rule to have the same breakdown performance between a normal (non-DTI process) and a DTI process. The design rule, in effect, requires the increase of the isolation spacing between the IC devices to provide equivalent breakdown voltage performance between a non-DTI process insulating structure and a DTI process insulating structure. However, increasing the isolation spacing will also increase the area of the chip used by the semiconductor devices.

Disclosed herein are semiconductor DTI structures, and methods of forming the same, that mitigate BV without sacrificing chip area. In other words, the DTI structures disclosed provide a solution to the degradation of the BV without increasing the isolation spacing as currently done. More specifically, the DTI structures disclosed have layouts and DTI trench profiles that are 1) integrated with STIs where DTI trenches are located on STIs, i.e., formed on a previously formed STI, and/or 2) are polygonal ring shaped to mitigate BV associated with semiconductor devices, e.g., Bipolar-CMOS-DMOS (BCD) devices, and others, that have a range of operating voltages, including relatively higher operating voltages above, but not limited to, 18-70 volts or greater. In other words, according to some example embodiments, disclosed is a DTI structure for use with a BCD IC to reduce or eliminate breakdown voltage (BDV) degradation of the DTI resulting from the operation of the BCD IC at higher voltages, as compared to operating the BCD IC at lower or “normal” operating voltages.

Also disclosed herein are fabrication processing sequences to form the disclosed DTI embodiments. According to an example DTI embodiment including the location of DTIs on STIs, the DTI process sequence includes the following: 1) form the active region/area of the device, which includes the active transistor regions of the device, etc., 2) using etching, patterning, and deposition techniques and processes, form the device STIs used for electrically isolating regions of the semiconductor device, and 3) using similar techniques as those used for forming the DTIs, using photolithographic processes with an additional mask to etch and form the DTIs located at one or more of the STIs.

Additional features associated with the disclosed DTI structures includes the rounding of the bottom of the DTI trenches, thereby providing a DTI structure that minimizes or reduces the probability of structural dislocations, etc. near the bottom of the DTI trenches formed during the fabrication processes. According to an example embodiment, the DTI trench depth is greater than 18 um.

Disclosed is a DTI structure for use with a BCD IC to reduce or eliminate breakdown voltage (BDV) degradation of the DTI resulting from the operation of the BCD IC at higher voltages, as compared to operating the BCD IC at lower or “normal” operating voltages. Some example voltage ranges of operation of the disclosed DTI structures include devices having a voltage breakdown in the range of about 6V to about 70V or higher.

According to some embodiments, the DTI structures disclosed herein include, but are not limited to, the following.

Embodiment 1A: One or more DTIs and associated trenches located on STIs.

Embodiment 1B: DTI structure, including the location of DTIs on STIs, where the DTI trench sidewalls are tapered and the DTI trench bottom has a round bottom.

Embodiment 1C: A DTI structure includes a trench with a channel stop implant layer formed along the trench bottom and trench side surfaces.

Embodiment 2A: A single DTI structure located in a STI area of an IC including a DTI polygon layout that includes 5 or more sides, where the DTI ring is not required to be located on one or more STIs.

Embodiment 2B: A single DTI structure located in a STI area of an IC including a DTI polygon layout that includes 5 or more sides, where the DTI ring is located on one or more STIs.

Embodiment 3A: A DTI structure located in an STI area of an IC including a multi DTI ring layout with 2 or more DTI rings, which are polygon shaped, each DTI ring including 5 or more sides, where the DTI rings are not required to be located on one or more STIs.

Embodiment 3B: A DTI structure located in an STI area of an IC including a multi DTI ring layout with 2 or more DTI rings, which are polygon shaped, each DTI ring including 5 or more sides, where the DTI rings are located on one or more STIs.

Method and/or processing to form at least some of the embodiments above, forming a DTI or DTI ring structure by initially fabricating the active region/area of the chip, then performing STI processes to form the STI region and, after the formation of the STI region, forming the DTI ring structure.

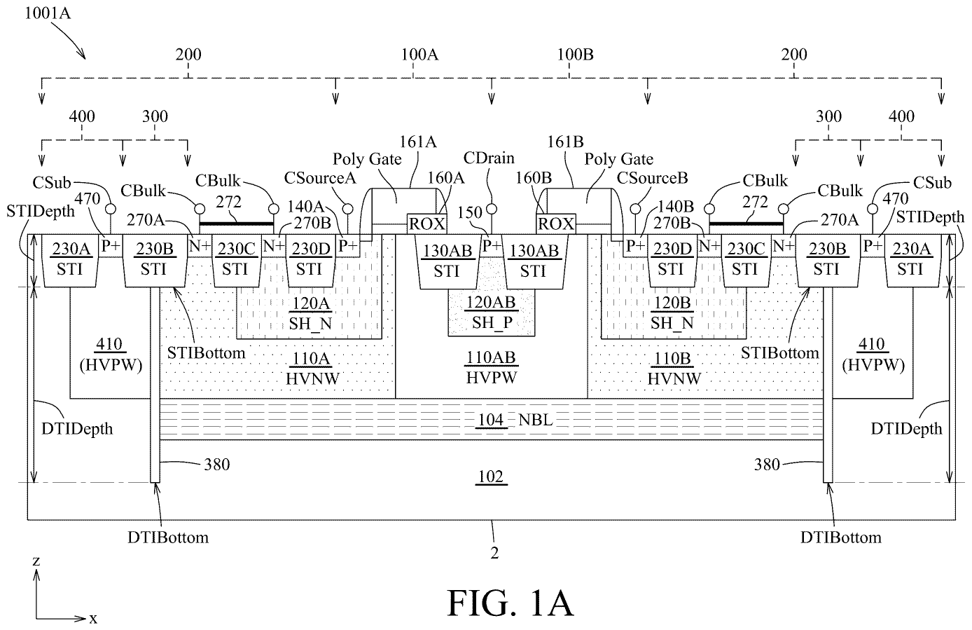

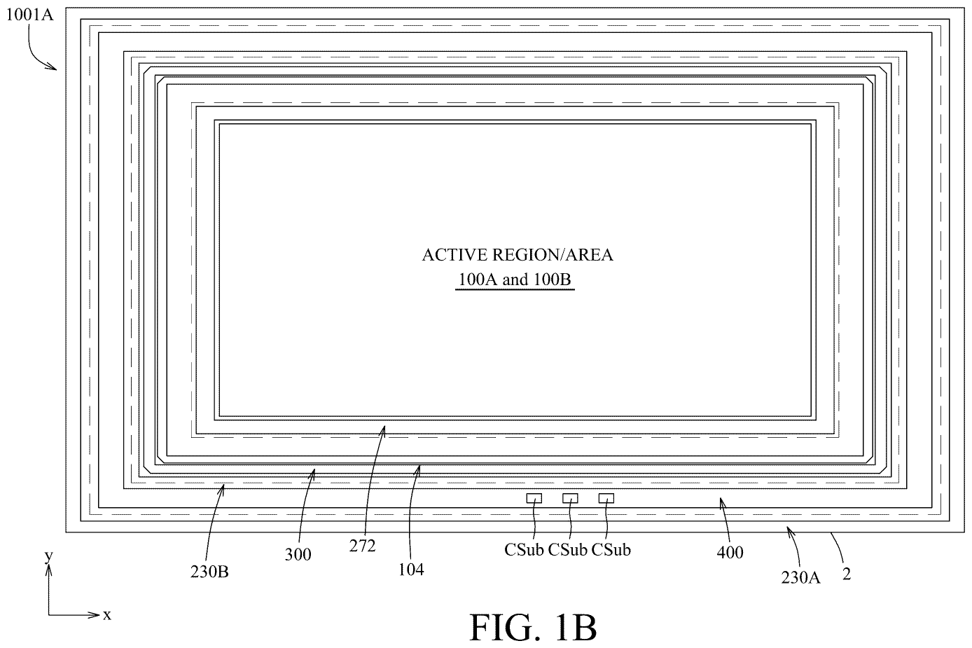

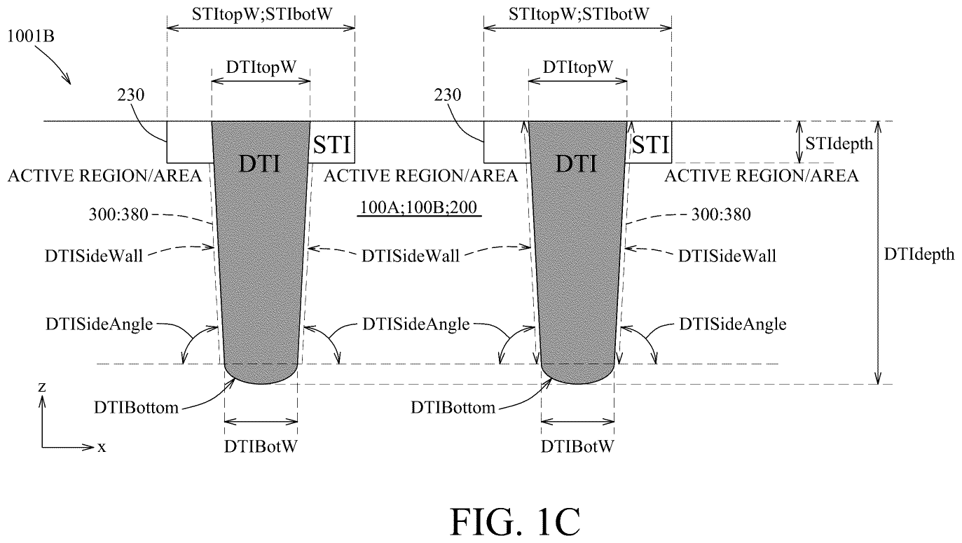

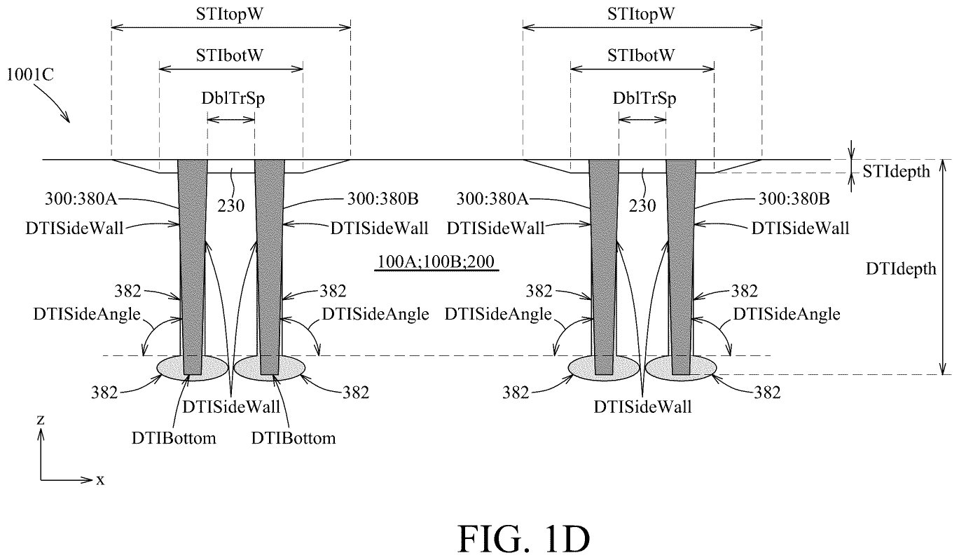

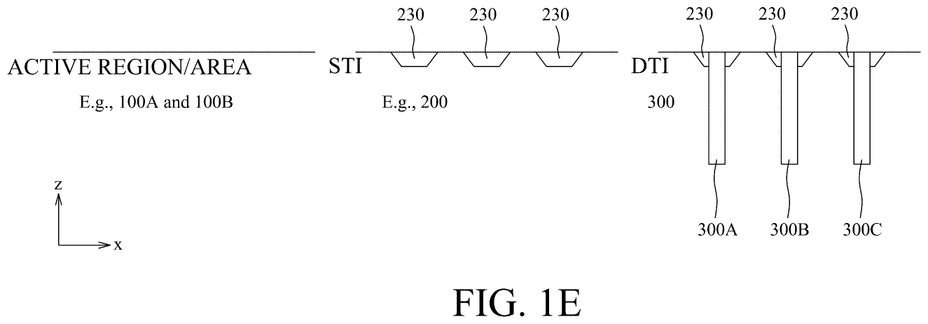

With reference to FIG. 1A, shown is a cross sectional view of an integrated circuit (IC), with chip boundary 2, including a deep trench isolation (DTI) structure according to an example embodiment of this disclosure, the DTI structure 1001A having a structure (Embodiment 1A) including first and second DTI structures 300 located on and extending through respective STI structures 230B, where DTI trenches 380 are formed to extend entirely through the STI 230B trench bottoms, STIBottom. FIG. 1B is a top view of the IC including the DTI structure shown in FIG. 1A. According to the example embodiment shown, the semiconductor device includes forming a doped buried layer in a substrate underneath an active region/area and STI structures; forming a plurality of high voltage wells (HVWs) on the doped buried layer; forming the active region/area in the HVWs; and forming the DTI structures to have DTI trench depths deeper than a depth of the doped buried layer and deeper than a depth of the HVWs.

More specifically, and with reference to FIGS. 1A and 1B, the disclosed IC structure includes the following.

A semiconductor substrate 102, a N type buried layer (NBL) 104 formed thereon, and formed on the NBL 104 and substrate 102 are an active region/area including transistor or active regions 100A and 100B, and STI regions 200, the STI regions including a DTI structure region 300 and an isolation ring structure 400.

Transistor regions 100A and 100B include a common drain structure having a high voltage P well (HVPW) 110AB operatively associated with the drain/gate of transistors 100A and 100B, STIs 130AB and shallow P well (SHP) 120AB are formed in HVPW 110AB and a P+ doped drain region 150 and contact CDrain are formed in SHP 120AB.

Transistor region 100A and STI region 200 further include a high voltage N well (HVNW) 110A operatively associated with the source/gate of transistor 100A. STIs 230A, 230B, 230C and 230D, and shallow N well (SHN) 120A are formed in HVNW 110A and a P+ doped source region 140A and contact CSourceA is formed in SHN 120A. In addition, the structure of transistor 100A and STI region 200 includes P doped region 470 operatively connected to contact CSub, and N doped regions 270A and 270B operatively connected to contact CBulk and N+ pick up ring 272. A recessed oxide (ROX) 160A and polycrystalline silicon (poly) gate 161A are formed to provide for the gate operation of transistor structure 100A.

Transistor region 100B and STI region 200 further include a high voltage N well (HVNW) 110B operatively associated with the source/gate of transistor 100B. STIs 230A, 230B, 230C and 230D, and shallow N well (SHN) 120B are formed in HVNW 110B and a P+doped source region 140B and contact CSourceB is formed in SHN 120B. In addition, the structure of transistor 100B and STI region 200 includes P doped region 470 operatively connected to contact CSub, and N doped regions 270A and 270B operatively connected to contact CBulk and N+pick up ring 272. A recessed (ROX) 160B and poly gate 161B are formed to provide for the gate operation of transistor structure 100B.

The STI region 200 adjacent each of the transistor regions 100A and 100B further includes HVPW 410 adjacent to HVNW 110A and HVPW 410 adjacent to HVNW 110B. In addition, a DTI structure 300 is provided, the DTI structure having a DTI trench 380 etched or formed at a boundary of HVPW 410 and HVNW 110A operatively associated with transistor region 100A, and etched or formed at a boundary of HVPW 410 and HVNW 110B operatively associated with transistor region 100B. As shown, the DTI trench 380 is located at the location of STI 230B where STI 230B extends a depth STIDepth. The DTI trench 380 extends a distance DTIDepth through the STI bottom surface STIbottom. Furthermore, the DTI trench 380 extends entirely through the HVPW 410 and HVNW 110A, and entirely through the NBL 104 into substrate 102 where DTI bottom DTIBottom is shown in FIG. 1A.

FIG. 1B provides a top view of the semiconductor device structure shown in FIG. 1A within a chip area 2, illustrating the active region/area 1001A and 100B, encircled by N+pick up ring 272, which is encircled by NBL 104, which is encircled by DTI structure or ring 300, which is encircled by isolation ring 400 having contacts Csub, and further including STIs 230A and 230B.

While the semiconductor device structure shown in FIGS. 1A and 1B includes a P type metal oxide semiconductor (MOS) transistor structure, it is to be understood that other transistor structures are within the scope of this disclosure, such as but not limited to, N type MOS transistor structures.

With reference to FIG. 1C, shown is a cross sectional detail view of a DTI structure 1001B (Embodiment 1B) according to an example embodiment of this disclosure, the DTI structure including first and second DTI structures 300, located on and extending through respective STI structures 230, where the DTI trenches 380 have tapered sidewalls DTISideWall and rounded trench bottoms TBottom. The DTI tapered side walls provide a more consistent forming of the DTI dielectric filler material by minimizing, reducing or eliminating potential voids of the DTI trench filled dielectric material during the dielectric deposition process, such as, but not limited to, chemical vapor deposition (CVD) or atomic layer deposition (ALD). The rounding of the DTI trench bottom during the etching process of DTIBottom also minimizes, reduces or eliminates potential voids of the DTI trench filled dielectric material during the dielectric deposition process as well as reducing or minimizing any trench bottom DTBottom structural dislocations or imperfections, thereby improving the performance of the semiconductor device and/or improving the production yield of the device during fabrication.

According to an example embodiment, the DTIdepth is greater than about 18 um; the DTITopW:DTITopW is about 15:18, and the taper angle of the DTISideWalls is from about 90 degrees to about 88 degrees, relative to an orthogonal axis of the DTI trench 380 as shown in FIG. 1C.

Other structural features of Embodiment 1B 1001B, include the STI width, STItopW and STIbotW, greater than a DTI trench width DTItopW and DTIBottom; forming the DTI trench 380 tapered side walls DTISideWall a DTI trench top width DTItopW is greater than a DTI trench bottom width DTIbotW.

With reference to FIG. 1D, shown is a cross sectional detail view of another DTI structure 1001C (Embodiment 1C) according to an example embodiment of this disclosure, the DTI structure including first and second DTI structures 300 located on and extending through respective STI structures 230, where each of the first and second DTI structures 300 have two twin trenches 380A and 380B spaced a distance DblTrSp from one another, and each of the two trenches 380A and 380B has a channel stop layer 382 within the DTI trenches 380A and 380B, the channel stop layer 382 including the implantation of ions distributed along the DTI trench sidewalls DTSideWall and along the DTI trench bottom DTIBottom.

The twin DTI trench layout of Embodiment 1C 1001C provides a DTI structure that can be more precisely controlled during the fabrication process, relative to a single equivalently functioning DTI structure. The channel-stopper or channel-stop layer 382 can produced by implantation or diffusion of ions, by growing or patterning, or other isolation methods in semiconductor material with the primary function being to limit the spread of the channel area of the DTI trench, or DTISideWalls to prevent the formation of parasitic channels.

With reference to FIG. 1E, shown is an IC fabrication processing sequence to form a plurality of DTI trenches on STIs according to an example embodiment of this disclosure, the sequence including 1) an active region/area processing stage to form transistor regions, e.g., 100A and 100B, as well as the underlying well regions and doped regions of the device, 2) a STI formation processing stage to form the STI regions 230 and 3) a DTI 300 formation processing stage to form DTI structures, e.g. 300A, 300B and 300C, on one or more of the STIs 230. Not shown, but also produced during this process sequence, could be other STIs 230 adjacent and to the right of the DTI structure 300 shown.

According to an example embodiment of this disclosure, and with reference to FIGS. 1A-1E,
STIdepth is about 400 A;
STItopW is not bound by any limits;
STIbotW is not bound by any limits;
DTIdepth is from about 19 um to 24 um;
DTItopW is from about 1.0 um to about 1.3 um;
DTIbotW is from about 0.9 um to about 1.2 um;
DblTrSp is equal to or greater than about 1.5 um;
BCDdist is equal to or greater than about 6 um
W/D ratio is from about 15 to about 21, where W/D ratio=DTItopW/DTIdepth. For example, if DTIdepth=22 um and DTItopW=1.2 um, then W/D ratio=18.3.

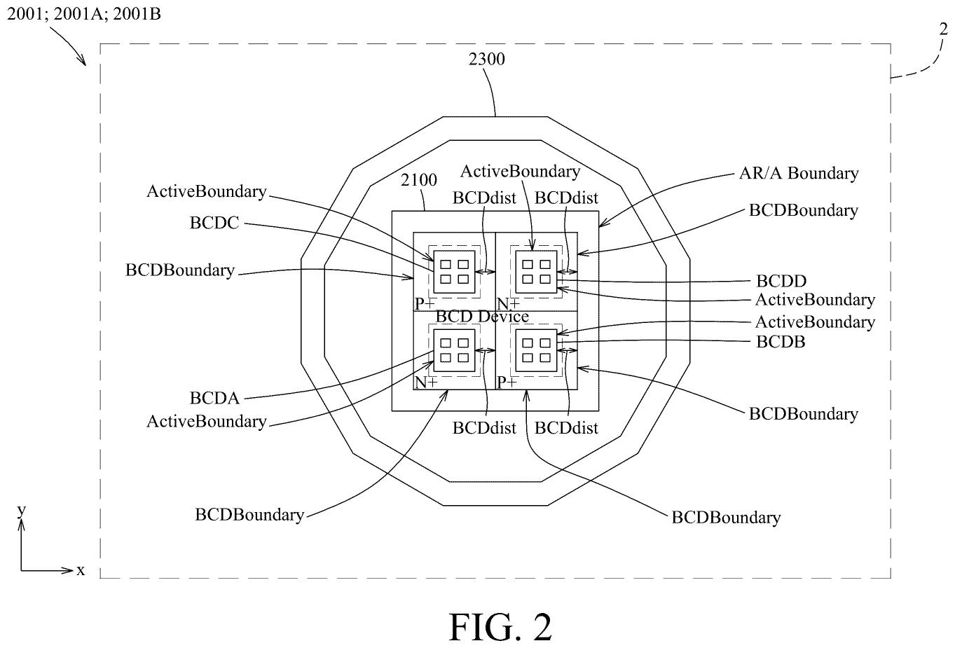

With reference to FIG. 2, shown is a top view of an IC die or structure 2001 bounded by wafer/die boundary 2, the IC die or structure 2001 including a DTI polygon ring shaped structure 2300 encircling an active region/area 2100 (defined by active region/area boundary AR/ABoundary) of the IC according to an example embodiment of this disclosure, the active region/area 2100 including a plurality of Bipolar-CMOS-DMOS (BCD) or other devices BCDA, BCDB, BCDC, and BCDD, (defined by BCD boundaries BCDBoundary) and the DTI polygon ring shaped structure 2300 not limited to being located at a STI (Embodiment 2A; 2001A) or where the DTI polygon ring shaped structure is located at a STI (Embodiment 2B; 2001B) where the DTI trench depth extends entirely through the STI trench bottom as previously described with reference to FIGS. 1A-1D.

As shown in FIG. 1E, the DTI ring structure 2300 is polygon shaped, e.g., octagonal, (as shown), pentagon, heptagon, hexagon, and other Shapes. More specifically, according to an example embodiment, the DTI ring structure 2300 is a ring that has 5 or more sides. Some advantages associated with the polygon ring shaped DTI structure include an improved performance of the DTI structure due to the manufacturability or fabrication of the polygon shaped DTI as compared to a rectangular or square shaped ring structure.

Other features of the illustrated IC die or structure 2001A; 2001B include a DTI polygon ring shaped structure 2300 encircling the active region/area 2100, where the active region/area 2100 has BCD device active boundaries ActiveBoundary are separated by a distance BCDist.

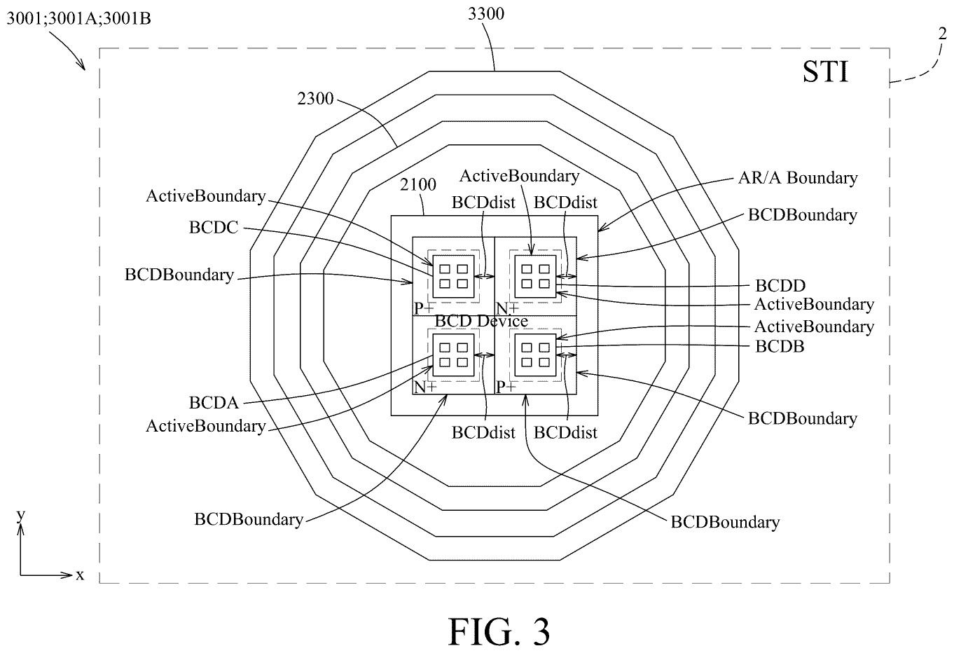

With reference to FIG. 3, shown is a top view of an IC die or structure 3001including a DTI polygon ring shaped structure 2300 and 3300 encircling an active region/area (defined by active region/area boundary AR/ABoundary) of the IC according to an example embodiment of this disclosure, the active region/area including a plurality of Bipolar-CMOS-DMOS (BCD) or other devices BCDA, BCDB, BCDC, and BCDD, (defined by BCD boundaries BCDBoundary) and the DTI polygon ring shaped structure including an inner polygon shaped DTI ring 2300, as previously described with reference to FIG. 2, and an outer polygon shaped DTI ring 3300, where each of the DTI polygon ring shaped structures 2300 and 3300 is not limited to being located at a STI (Embodiment 3A; 330A) or where each of the DTI polygon ring shaped structures 2300 and 3300 is located at a STI (Embodiment 3B: 3300B) where the DTI trench depth extends entirely through the STI trench bottom. While the number of DTI polygon shaped ring structures is two in this figure, the number can be any number N, where N is greater than 2 or more. According to an example embodiment, the DTI rings 2300 and 330 are spaced apart greater than about 2 um.

According to an example embodiment, the Embodiments 1A, 1B, 1C, 2A, 2B, 3A, and 3B are formed on one or more wafers made of a semiconducting material, where the DTI embodiment structures are built or formed thereon by conventional semiconductor fabrication techniques, including but not limited to photolithographic techniques such as applying a pattern/structure in a given layer by applying a photoresist layer, patterning the photoresist layer, developing the photoresist layer, and then etching, followed by planarizing and cleaning. While the specific semiconductor fabrication processes required to form the disclosed embodiments shown and described are not the focus of this disclosure, for completeness a general description of the semiconductor fabrication processes follows.

The semiconductor substrate materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF4), hexafluoroethane (C2F6), octafluoropropane (C3F8), fluoroform (CHF3), difluoromethane (CH2F2), fluoromethane (CH3F), trifluoromethane (CHF3), carbon fluorides, nitrogen (N2), hydrogen (H2), oxygen (O2), argon (Ar), xenon (Xe), xenon difluoride (XeF2), helium (He), carbon monoxide (CO), carbon dioxide (CO2), fluorine (F2), chlorine (Cl2), oxygen (O2), hydrogen bromide (HBr), hydrofluoric acid (HF), nitrogen trifluoride (NF3), sulfur hexafluoride (SF6), boron trichloride (BCl3), ammonia (NH3), bromine (Br2), nitrogen trifluoride (NF3), or the like, or combinations thereof in various ratios. For example, silicon dioxide can be wet etched using hydrofluoric acid and ammonium fluoride. Alternatively, silicon dioxide can be dry etched using various mixtures of CHF3, O2, CF4, and/or H2.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

Dielectric structures or layers of the devices disclosed can be made from any suitable combination of dielectric materials. Examples of dielectric materials may include silicon dioxide (SiO2), silicon nitride (Si3N4), silicon carbide (SiC), hafnium dioxide (HfO2), zirconium dioxide (ZrO2), aluminum oxide (Al2O3), silicon oxynitride (SiOxNy), hafnium oxynitride (HfOxNy) or zirconium oxynitride (ZrOxNy), or hafnium silicates (ZrSixOy) or zirconium silicates (ZrSixOy) or silicon carboxynitride (SiCxOyNz), or hexagonal boron nitride (hBN). Other dielectric materials may include tantalum oxide (Ta2O5), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material, discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

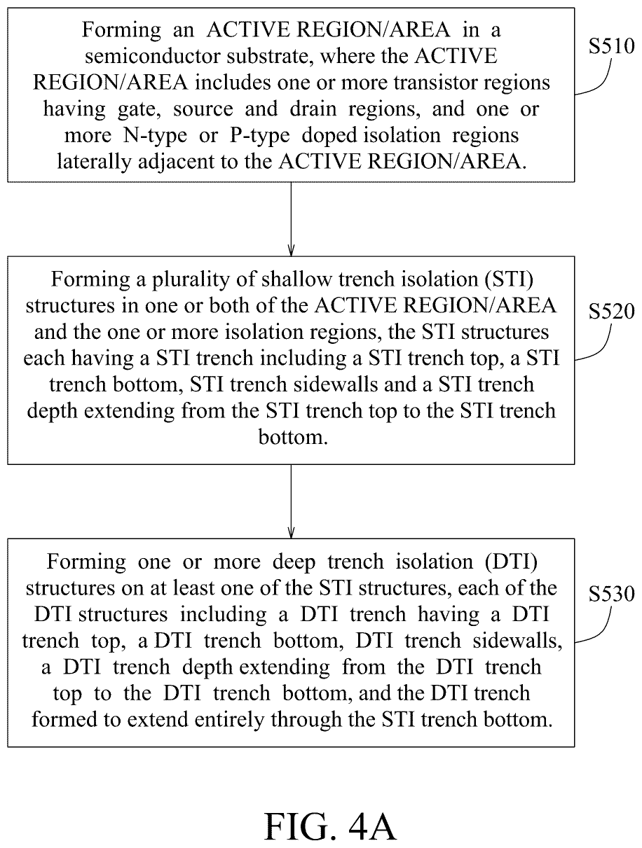

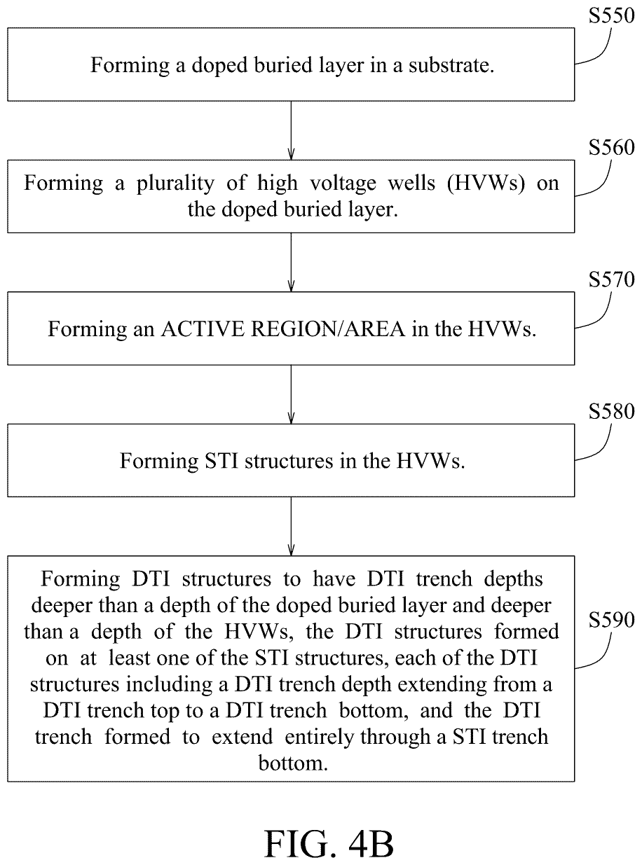

With reference to FIG. 4A, illustrated are various fabrication steps associated with the fabrication of an IC structure according to an example embodiment of the present disclosure.

At step S510, the method forms an active region/area in a semiconductor substrate, where the active region/area includes one or more transistor regions having gate, source and drain regions, and one or more N-type or P-type doped isolation regions laterally adjacent to the active region/area.

At step S520, the method forms a plurality of shallow trench isolation (STI) structures in one or both of the active region/area and the one or more isolation regions, the STI structures each having a STI trench including a STI trench top, a STI trench bottom, STI trench sidewalls and a STI trench depth extending from the STI trench top to the STI trench bottom.

At step S530, the method forms one or more deep trench isolation (DTI) structures on at least one of the STI structures, each of the DTI structures including a DTI trench having a DTI trench top, a DTI trench bottom, DTI trench sidewalls, a DTI trench depth extending from the DTI trench top to the DTI trench bottom, and the DTI trench formed to extend entirely through the STI trench bottom.

With reference to FIG. 4B, illustrated are various fabrication steps associated with the fabrication of an IC structure according to another example embodiment of the present disclosure.

At step S550, the method forms a doped buried layer in a substrate.

At step S560, the method forms a plurality of high voltage wells (HVWs) on the doped buried layer.

At step S570, the method forms an active region/area in the HVWs.

At step S580, the method forms STI structures in the HVWs.

At step S590, the method forms DTI structures to have DTI trench depths deeper than a depth of the doped buried layer and deeper than a depth of the HVWs, the DTI structures formed on at least one of the STI structures, each of the DTI structures including a DTI trench depth extending from a DTI trench top to a DTI trench bottom, and the DTI trench formed to extend entirely through a STI trench bottom.

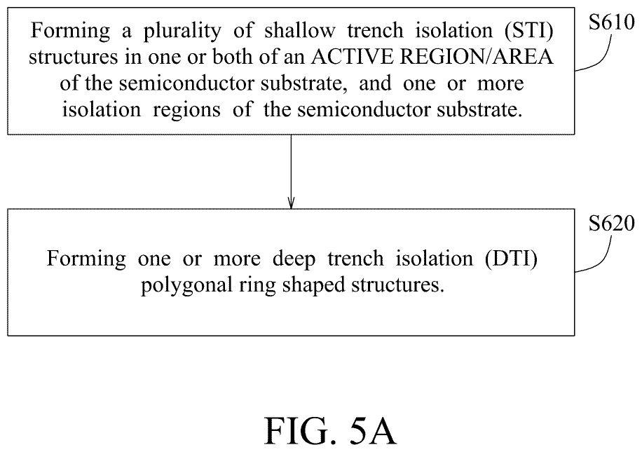

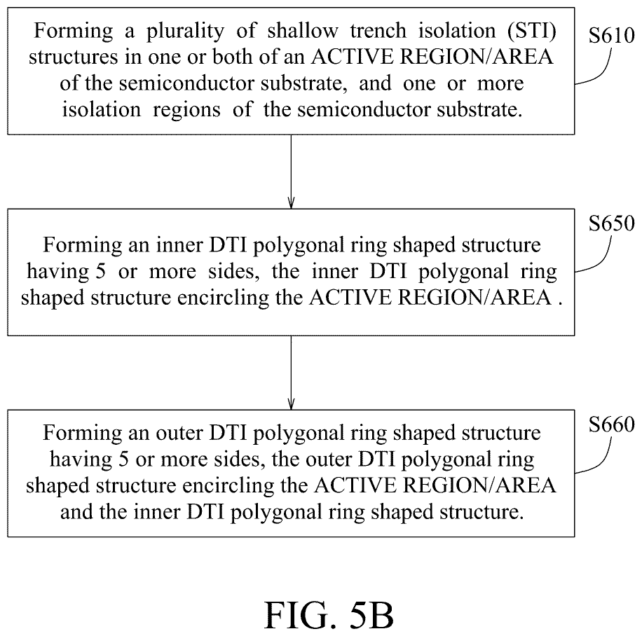

With reference to FIG. 5A, illustrated are various fabrication steps associated with the fabrication of an IC structure according to an example embodiment of the present disclosure.

At step S610, the method forms a plurality of shallow trench isolation (STI) structures in one or both of an active region/area of the semiconductor substrate, and one or more isolation regions of the semiconductor substrate.

At step S620, the method forms one or more deep trench isolation (DTI) polygonal ring shaped structures.

With reference to FIG. 5B, illustrated are various fabrication steps associated with the fabrication of an IC structure according to another example embodiment of the present disclosure.

At step S610, the method forms a plurality of shallow trench isolation (STI) structures in one or both of an active region/area of the semiconductor substrate, and one or more isolation regions of the semiconductor substrate.

At step S650, the method forms an inner DTI polygonal ring shaped structure having 5 or more sides, the inner DTI polygonal ring shaped structure encircling the active region/area.

At step S660, the method forms an outer DTI polygonal ring shaped structure having 5 or more sides, the outer DTI polygonal ring shaped structure encircling the active region/area and the inner DTI polygonal ring shaped structure.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed DTI structures, and methods of forming the same, provide for an improved BV performance of an IC device, whereby the BV degradation of the device is minimized, reduced or eliminated during the use of the device at relatively high voltages. An additional advantage is the improved BV performance of the disclosed DTI structures is achieved without increasing device spacing to achieve similar BV performance, where increasing the isolation spacing also increases the area of the chip used by the semiconductor device(s).

In the following, some further embodiments are described.

In a nonlimiting illustrative embodiment, a method of forming a deep trench isolation structure in a semiconductor substrate or an IC comprising: forming an active region/area in a semiconductor substrate, the active region/area including one or more transistor regions having gate, source and drain regions, and one or more N-type or P-type doped isolation regions laterally adjacent to the active region/area; forming a plurality of shallow trench isolation (STI) structures in one or both of the active region/area and the one or more isolation regions, the STI structures each having a STI trench including a STI trench top, a STI trench bottom, STI trench sidewalls and a STI trench depth extending from the STI trench top to the STI trench bottom; and forming one or more deep trench isolation (DTI) structures on at least one of the STI structures, each of the DTI structures including a DTI trench having a DTI trench top, a DTI trench bottom, DTI trench sidewalls, a DTI trench depth extending from the DTI trench top to the DTI trench bottom, and the DTI trench formed to extend entirely through the STI trench bottom.

In another nonlimiting illustrative embodiment, a semiconductor device or IC or semiconductor structure comprising: a semiconductor substrate; an active region/area formed on the semiconductor substrate, the active region/area including one or more transistor regions having gate, source and drain regions, one or more N-type or P-type doped isolation regions laterally adjacent to the active region/area; a plurality of shallow trench isolation (STI) structures in one or both of the active region/area and the one or more isolation regions, the STI structures each having a STI trench including a STI trench top, a STI trench bottom, STI trench sidewalls and a STI trench depth extending from the STI trench top to the STI trench bottom; and one or more deep trench isolation (DTI) structures on at least one of the STI structures, each of the DTI structures including a DTI trench having a DTI trench top, a DTI trench bottom, DTI trench sidewalls, a DTI trench depth extending from the DTI trench top to the DTI trench bottom, and the DTI trench formed to extend entirely through the STI trench bottom.

In another nonlimiting illustrative embodiment, a method of forming an integrated circuit (IC) or semiconductor device including a deep trench isolation structure in a semiconductor substrate comprising: forming a plurality of shallow trench isolation (STI) structures in one or both of an active region/area of the semiconductor substrate, and one or more isolation regions of the semiconductor substrate, the STI structures each having a STI trench including a STI trench top, a STI trench bottom, STI trench sidewalls and a STI trench depth extending from the STI trench top to the STI trench bottom; and forming one or more deep trench isolation (DTI) polygonal ring shaped structures, the DTI polygonal ring shaped structure each having a DTI trench including a DTI trench top width, a DTI trench bottom, DTI trench sidewalls, and a DTI trench depth extending from the DTI trench top to the DTI trench bottom.

In another nonlimiting illustrative embodiment, a semiconductor device or semiconductor structure or IC comprising: a plurality of shallow trench isolation (STI) structures in one or both of an active region/area of a semiconductor substrate, and one or more isolation regions of the semiconductor substrate, the STI structures each having a STI trench including a STI trench top, a STI trench bottom, STI trench sidewalls and a STI trench depth extending from the STI trench top to the STI trench bottom; and one or more deep trench isolation (DTI) polygonal ring shaped structures, the DTI polygonal ring shaped structure each having a DTI trench including a DTI trench top width, a DTI trench bottom, DTI trench sidewalls, and a DTI trench depth extending from the DTI trench top to the DTI trench bottom.

In another nonlimiting illustrative embodiment, a method of forming an integrated circuit (IC) or semiconductor device including a deep trench isolation structure in a semiconductor substrate comprising: forming a plurality of shallow trench isolation (STI) structures in one or both of an active region/area of the semiconductor substrate, and one or more isolation regions of the semiconductor substrate, the STI structures each having a STI trench including a STI trench top, a STI trench bottom, STI trench sidewalls and a STI trench depth extending from the STI trench top to the STI trench bottom; and forming one or more deep trench isolation (DTI) polygonal ring shaped structures, the DTI polygonal ring shaped structure each having a DTI trench including a DTI trench top width, a DTI trench bottom, DTI trench sidewalls, and a DTI trench depth extending from the DTI trench top to the DTI trench bottom; the method further comprising: forming an inner DTI polygonal ring shaped structure having 5 or more sides, the inner DTI polygonal ring shaped structure encircling the active region/area; forming an outer DTI polygonal ring shaped structure having 5 or more sides, the outer DTI polygonal ring shaped structure encircling the active region/area and the inner DTI polygonal ring shaped structure; and forming the one or more DTI polygonal ring shaped structures on at least one of the STI structures, each of the DTI trenches formed to extend entirely through a respective STI trench bottom.

In another nonlimiting illustrative embodiment, a semiconductor device or semiconductor structure or IC comprising: a plurality of shallow trench isolation (STI) structures in one or both of an active region/area of a semiconductor substrate, and one or more isolation regions of the semiconductor substrate, the STI structures each having a STI trench including a STI trench top, a STI trench bottom, STI trench sidewalls and a STI trench depth extending from the STI trench top to the STI trench bottom; and one or more deep trench isolation (DTI) polygonal ring shaped structures, the DTI polygonal ring shaped structure each having a DTI trench including a DTI trench top width, a DTI trench bottom, DTI trench sidewalls, and a DTI trench depth extending from the DTI trench top to the DTI trench bottom, wherein the inner DTI polygonal ring shaped structure has 5 or more sides, the inner DTI polygonal ring shaped structure encircles the active region/area; the outer DTI polygonal ring shaped structure has 5 or more sides, the outer DTI polygonal ring shaped structure encircles the active region/area and the inner DTI polygonal ring shaped structure; and the one or more DTI polygonal ring shaped structures are located on at least one of the STI structures, each of the DTI trenches formed to extend entirely through a respective STI trench bottom.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a deep trench isolation structure in a semiconductor substrate comprising:
forming an active region in a semiconductor substrate, the active region including one or more transistor regions having gate, source and drain regions, and one or more N-type or P-type doped isolation regions laterally adjacent to the active region/area;
forming a plurality of shallow trench isolation (STI) structures in one or both of the active region and the one or more isolation regions, the STI structures each having a STI trench including a STI trench top, a STI trench bottom, STI trench sidewalls and a STI trench depth extending from the STI trench top to the STI trench bottom; and
forming one or more deep trench isolation (DTI) structures on at least one of the STI structures, each of the DTI structures including a DTI trench having a DTI trench top, a DTI trench bottom, DTI trench sidewalls, a DTI trench depth extending from the DTI trench top to the DTI trench bottom, and the DTI trench formed to extend entirely through the STI trench bottom.

2. The method of claim 1, wherein the STI trench has a STI trench width greater than a DTI trench width.

3. The method of claim 2, wherein a ratio of a DTI trench width to the DTI trench depth is about 15:18, and the DTI trench depth is greater than about 18 um.

4. The method of claim 1, further comprising:
forming the DTI trench bottom to have a rounded end shape.

5. The method of claim 1, further comprising:
forming the DTI trench to have tapered sidewalls, the tapered side walls formed such that a DTI trench top width is greater than a DTI trench bottom width.

6. The method of claim 5, wherein the DTI tapered sidewalls form an angle of about 88 degrees to about 90 degrees relative to an orthogonal axis of the DTI trench.

7. The method of claim 1, further comprising:
forming a channel stop layer within the DTI trench, the channel stop layer including the implantation of ions distributed along the DTI trench sidewalls and along the DTI trench bottom.

8. The method of claim 7, further comprising:
forming a doped buried layer in the substrate underneath the active region and STI structures;
forming a plurality of high voltage wells (HVWs) on the doped buried layer;
forming the active region in the HVWs; and
forming the DTI structures to have DTI trench depths deeper than a depth of the doped buried layer and deeper than a depth of the HVWs.

9. A semiconductor device comprising:
a semiconductor substrate;
an active region formed on the semiconductor substrate, the active region including one or more transistor regions having gate, source and drain regions,
one or more N-type or P-type doped isolation regions laterally adjacent to the active region/area;
a plurality of shallow trench isolation (STI) structures in one or both of the active region and the one or more isolation regions, the STI structures each having a STI trench including a STI trench top, a STI trench bottom, STI trench sidewalls and a STI trench depth extending from the STI trench top to the STI trench bottom; and
one or more deep trench isolation (DTI) structures on at least one of the STI structures, each of the DTI structures including a DTI trench having a DTI trench top, a DTI trench bottom, DTI trench sidewalls, a DTI trench depth extending from the DTI trench top to the DTI trench bottom, and the DTI trench formed to extend entirely through the STI trench bottom.

10. The device of claim 9, wherein the STI trench has a STI trench width greater than a DTI trench width.

11. The device of claim 10, wherein a ratio of the DTI trench width to the DTI trench depth is about 15:18, and the DTI trench depth is greater than about 18 um.

12. The device of claim 9, wherein the DTI trench bottom has a rounded end shape.

13. The device of claim 9, wherein DTI trench has tapered sidewalls, the tapered side walls formed such that a DTI trench top width is greater than a DTI trench bottom width.

14. The device of claim 13, wherein the DTI tapered sidewalls form an angle of about 88 degrees to about 90 degrees relative to an orthogonal axis of the DTI trench.

15. The device of claim 9, further comprising:
a channel stop layer within the DTI trench, the channel stop layer including the implantation of ions distributed along the DTI trench sidewalls and along the DTI trench bottom.

16. The device of claim 15, further comprising:
a doped buried layer in the substrate underneath the active region and STI structures; and
a plurality of high voltage wells (HVWs) on the doped buried layer;
wherein the active region is formed on the HVWs, and the DTI structures have DTI trench depths deeper than a depth of the doped buried layer and deeper than a depth of the HVWs.

17. A method of forming an integrated circuit (IC) including a deep trench isolation structure in a semiconductor substrate comprising:
forming a plurality of shallow trench isolation (STI) structures in one or both of an active region of the semiconductor substrate, and one or more isolation regions of the semiconductor substrate, the STI structures each having a STI trench including a STI trench top, a STI trench bottom, STI trench sidewalls and a STI trench depth extending from the STI trench top to the STI trench bottom; and
forming one or more deep trench isolation (DTI) polygonal ring shaped structures, the DTI polygonal ring shaped structure each having a DTI trench including a DTI trench top width, a DTI trench bottom, DTI trench sidewalls, and a DTI trench depth extending from the DTI trench top to the DTI trench bottom.

18. The method of claim 17, wherein forming the one or more DTI polygonal ring shaped structures further comprises:
forming an inner DTI polygonal ring shaped structure having 5 or more sides, the inner DTI polygonal ring shaped structure encircling the active region/area; and
forming an outer DTI polygonal ring shaped structure having 5 or more sides, the outer DTI polygonal ring shaped structure encircling the active region and the inner DTI polygonal ring shaped structure.

19. The method of claim 17, further comprising:
forming the one or more DTI polygonal ring shaped structures on at least one of the STI structures, each of the DTI trenches formed to extend entirely through a respective STI trench bottom.

20. The method of claim 19, further comprising:
forming the DTI trench bottom to have a rounded end shape; and
forming the DTI to have tapered sidewalls, the tapered side walls formed such that a DTI trench top width is greater than a DTI trench bottom width,
wherein the STI trench has a STI trench width greater than a DTI trench width, a ratio of the DTI trench width to the DTI trench depth is about 15:18, and the DTI trench depth is greater than about 18 um.
